(19) United States
(12) Patent Application Publication
(10) Pub. No.: US 2008/0288698 A1
(43) Pub. Date: Nov. 20, 2008

(54) CARD READER CONTROLLING APPARATUS BASED ON SECURE DIGITAL PROTOCOL

(75) Inventors: Jin-min Lin, Taipei City (TW); Nei-chiung Perng, Taipei City (TW); Chih-jung Lin, Taoyuan City (TW)

Correspondence Address: KIRTON AND MCCONKIE, 60 EAST SOUTH TEMPLE,, SUITE 1800, SALT LAKE CITY, UT, 84111, US

(73) Assignee: GENESYS LOGIC, INC., Shindian City (TW)

(21) Appl. No.: 12/120,738

(22) Filed: May 15, 2008

(30) Foreign Application Priority Data
May 16, 2007 (TW) 096207911

(51) Int. Cl. H05K 7/10

(52) U.S. Cl. 710/301

(57) ABSTRACT

The proposed invention discloses a card reader controlling apparatus based on Secure Digital (SD) protocol, which comprises a high-speed bus interface, at least one SD host, at least one SD connection interface and SDIO connection interface (SD/SDIO interface), at least one bridge, and at least one other specific memory card connecting interface. The card reader controlling apparatus according to the proposed invention is capable of directly accessing data from/to an input/output device compatible with the SDIO connection interface (e.g. an SD card) or one other specific memory card via the high-speed bus interface. Thus, multiple format conversions performed by other peripheral bus interfaces (such as an USB interface) as the prior art can be by-passed or eliminated.

### FIELD OF THE INVENTION

The present invention relates to a card reader controlling apparatus based on Secure Digital (SD) protocol, and more particularly to a card reader controlling apparatus which is capable of directly accessing an SD card or an input/output device compatible with a Secure Digital input/output (SDIO) connection interface.

### BACKGROUND OF THE INVENTION

Memory cards nowadays are wide-spreading used as storage media in various digital consumer electronics. Most of memory cards treated as storage devices were fabricated with solid-state electronics, and NAND flash is the majority technology. Generic flash memory cards include, for examples, Secure Digital (SD) card, Multimedia Card (MMC), Smart Media (SM), Memory Stick (MS), Compact Flash card (CF), xD-Picture (xD) and so on.

Various card readers for accessing the above-mentioned flash memory cards are widely applied in different memory card access systems, also known as card readers, and are categorized into built-in card readers and external card readers. For example, built-in card readers are embedded in host systems such as personal computers, digital still cameras, smart phones, and many other consumer electronic products. External card readers are external devices connected to the above-mentioned host systems through external cables based over parallel interfaces, Universal Serial Bus (USB), Institute of Electrical and Electronics Engineers (IEEE) 1394, or wireless communications.

Please refer to FIG. 2, which shows a functional block diagram of a conventional system associated with memory card access. The memory card access system 20 comprises a central processing unit (CPU) 210, a northbridge chipset 220, a main memory 230, a southbridge chipset 240, a card reader controller 250, and a memory card 260. When the CPU 210 needs to read data from the memory card 260, it sends a read command to the northbridge chipset 220. After the high-speed bus interface 271 of the northbridge 220 translates the read command into a high-speed bus read command, the high-speed bus read command is transmitted to the southbridge chipset 240. Then, the southbridge chipset 240 employs a peripheral bus interface 272 to translate the high-speed bus read command into a peripheral bus read command and transmits the peripheral bus read command to the card reader controller 250. Finally, the card reader controller 250 specifies a built-in specific memory card interface 273 to translate the peripheral bus read command into specific memory card format read command and transmits the specific memory card format read command to a memory card controller 274 disposed within the memory card 260. After the memory card controller 274 receives the specific memory card format read command, it reads the requested data from flash memory, encapsulates the requested data into the specific memory card format, and feedbacks to the card reader controller 250. The response will be backtracked to CPU 210 following the previous path. That is, the card reader controller 250 translates the specific memory card format data into a peripheral bus data and transmits the peripheral bus data to the southbridge chipset 240. The southbridge chipset 240 translates the peripheral bus data into a high-speed bus data and transmits the high-speed bus data to the northbridge chipset 220. Finally, the northbridge chipset 220 stores the high-speed bus data to the main memory 230 for need of the CPU 210.

On the contrary, when the CPU 210 needs to write data into the memory card 260, it sends out a write command. The route of sending the write command to the memory card 260 is the same as sending the read command. The nothbridge chipset 220 accesses data to be written from the main memory 230. Then, the high-speed bus interface 271 translates the data to be written into a high-speed bus data and transmits the high-speed bus data to the southbridge chipset 240. Then, the peripheral bus interface 272 of the southbridge chipset 240 translates the high-speed bus data into a peripheral bus interface data and transmits the peripheral bus interface data to the card reader controller 250. The specific memory card interface 273 of the card reader controller 250 translates the peripheral bus interface data into a specific memory card data and transmits the specific memory card data to the memory card controller 274 of the memory card 260. Finally, the memory card controller 274 stores data to be written within flash memory.

However, a disadvantage of the prior art is that there are too many transmission protocols and translation operations during a read or a write period. This does not only result in data transmission delays, but also burdens a host system with computation complexity to lower the whole host system performance.

Besides, although the present peripheral bus can reach a transmission rate of 480 Megabit per second (Mbps), i.e., USB, to possibly satisfy transmission rates required by all memory cards on the market, the requirements for massive portable digital data and rapid technology development are still continuously increased. A high-speed bus (e.g., a peripheral component interconnect Express, PCI-E) using a transmission rate more than 2.5 Gigabit per second (Gbps) could greatly satisfy demands of high-speed and large-capacity memory cards in the future. For example, SD cards are widely used by the public now. If there is an appropriate card reader controlling apparatus designed for raising an access rate and convenience of SD card, this will meet the public demand on SD card.

Accordingly, it is necessary to set forth a card reader controlling apparatus based on SD protocol, which is improved for great operation efficiency and resource saving of a host system in access of data from a memory card.

### SUMMARY OF THE INVENTION

To withdraw the aforementioned drawback, a primary object of the present invention is to provide a card reader controlling apparatus based on SD protocol, which is capable of directly accessing an SD card or an input/output device compatible with an SDIO connection interface (an SDIO device). Accordingly, the present invention promotes the whole host system performance by eliminating a format translation procedure via a peripheral bus interface.

To achieve the above-mentioned object, the present invention sets forth a card reader controlling apparatus based on SD protocol, which comprises a high-speed bus interface, at least one SD host, at least one bridge, at least one SD card connection interface and SDIO connection interface (SD/SDIO interface), and at least one other specific memory card connection interface. When the card reader controlling apparatus based on SD protocol receives a high-speed bus format access command (a read command or a write command), the SD host translates the high-speed bus format access command into an SD format access command. If the access command needs to access an SD card or an SDIO device, the SD host proceeds to directly transmit data with the SD/SDIO interface for data access from or to the SD/SDIO device. On the contrary, if the high-speed bus format access command is to access one other specific memory card, the SD host translates the high-speed bus format access command into an SD format access command and transmits the SD format access command to the bridge. Then, the bridge translates the SD format access command into other specific memory card format access command and proceeds to transmit data with the other specific memory card through the other specific memory card connection interface.

Compared with the prior art, the card reader controlling apparatus of the present invention utilizes a high-speed bus interface on the basis of SD protocol to directly translates a high-speed bus format access command into an SD format access command so as to access data from/to an SD card or an SDIO device. This can eliminate command format translations through other peripheral bus interfaces (e.g., a USB interface) and shorten transmission time of commands and data, and diminish computation complexity of a card reader. In another aspect, when a user intends to access one other specific memory card, the card reader controlling apparatus of the present invention can utilize a specific bridge to translate SD format commands into other specific memory card format commands for supporting various types of memory card formats.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 shows a functional block diagram of a card reader controlling apparatus connected to a host system according to a preferred embodiment of the present invention; and

FIG. 2 shows a functional block diagram of a conventional memory card access system.

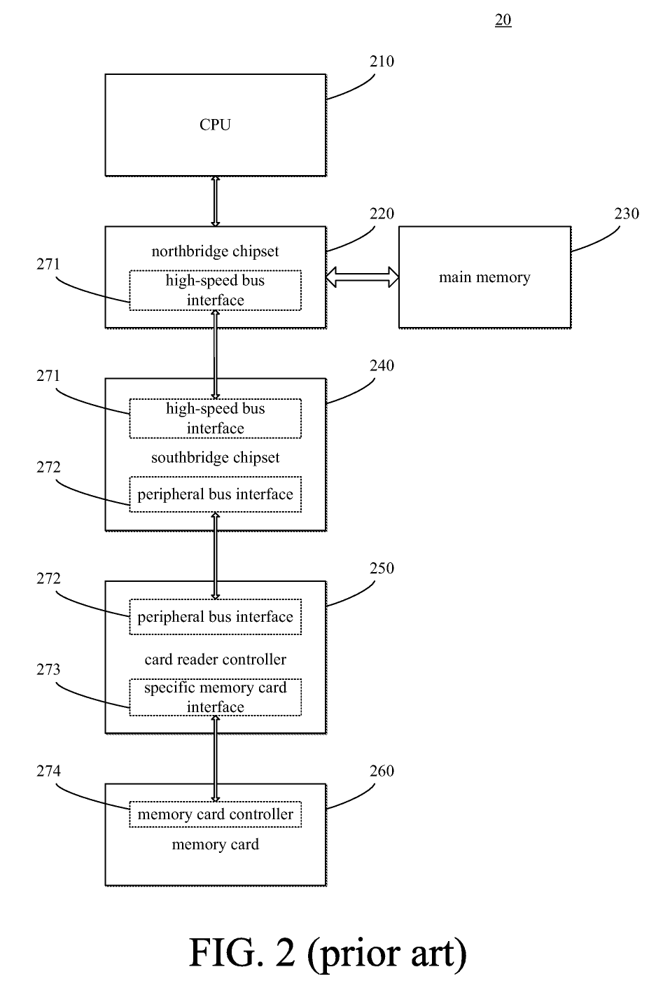

### DETAILED DESCRIPTION OF THE PREFERRED EMBODIMENTS

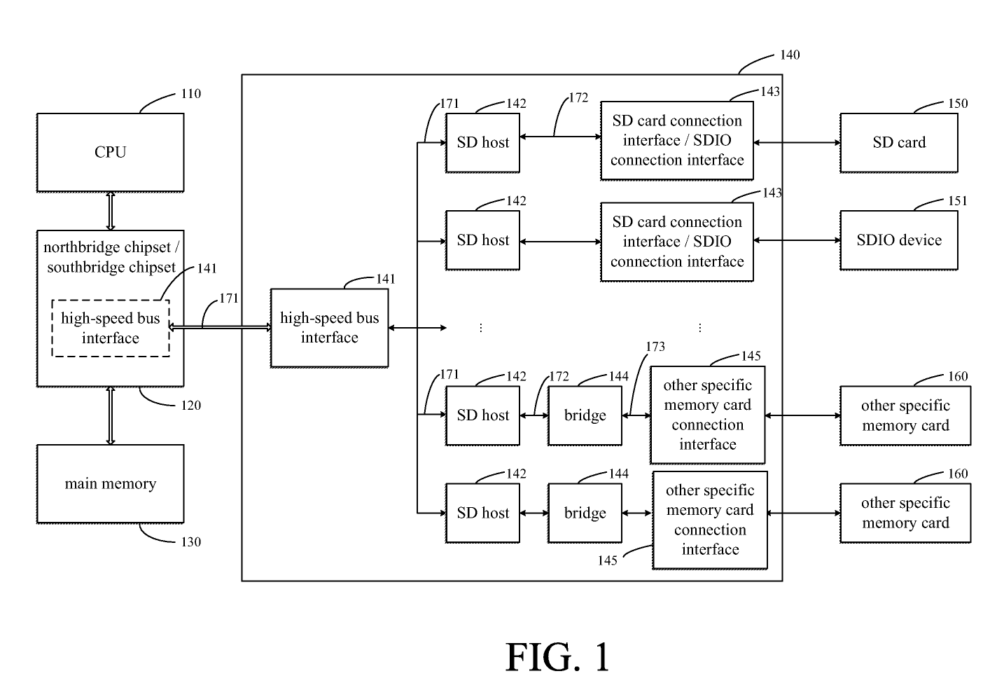

Please refer to FIG. 1, which shows a functional block diagram of a card reader controlling apparatus 140 connected to a host system, according to a preferred embodiment of the present invention. The host system comprises a CPU 110, a northbridge/southbridge chipset 120, and a main memory 130. The card reader controlling apparatus 140 interconnects the host system with at least one SD card 150 and/or at least one other specific memory card 160. In this embodiment, the card reader controlling apparatus 140 is implemented as a card reader controller, which primarily comprises a high-speed bus interface 141, at least one SD host 142, at least one SD card connection interface/SDIO connection interface 143, at least one bridge 144, and at least one other specific memory card connection interface 145. It is noted that the high-speed bus interface 141 is not restricted to any commonly known bus technology. In this embodiment, optimally it can also be a Peripheral Component Interconnect Express (PCI-E) bus interface or a Peripheral Component Interconnect (PCI) bus interface.

When the CPU 110 of the host system needs to access data from/to the SD card 150 or one other specific memory card 160, it sends a high-speed bus format access command 171 to the high-speed bus interface 141 of the card reader controlling apparatus 140 through the high-speed bus interface 141 of the northbridge/southbridge chipset 120. If the write command is issued to store data to a corresponding memory card, the data located in the main memory 130 is transmitted to the card reader controlling apparatus 140 through the northbridge/southbridge chipset 120. Then, the card reader controlling apparatus 140 stores the data into the memory card. On the contrary, if the read command is issued to read data from specific one of the memory cards 150, 151, or 160, the card reader controlling apparatus 140 reads the data from the specific one of the memory cards 150, 151, or 160 and then transmits the data to the main memory 130 through the northbride/southbridge chipset 120 for the need of CPU 110.

When the card reader controlling apparatus 140 receives the access command (read or write) from the high-speed bus interface 141 of the northbridge/southbridge chipset 120, the SD host 142 of the card reader controlling apparatus 140 translates the high-speed bus format access command 171 into an SD format access command 172 and transmits the SD format access command 172 to the corresponding SD card connection interface/SDIO connection interface 143. If the access command is issued to access data from/to the SD card 150 or an SDIO device 151, the SD format access command 172 is directly transmitted to the SD card connection interface/SDIO connection interface 143 from the SD host. Then, the SD card connection interface/SDIO connection interface 143 accesses data from/to the SD card 150 or the SDIO device 151 based on the SD format access command 172.

If the northbridge/southbridge chipset 120 needs to store data into the SD card 150 or the SDIO device 151, the route of sending the stored data and the related format conversions are the same as the above-mentioned access command to the SD card 150 or the SDIO device 151. If the CPU 110 needs to read data from the SD card 150, the SD host 142 translates data from the SD card 150 into high-speed bus format. Then, the data is transmitted to the northbridge/southbridge chipset 120 through the high-speed bus interface 141.

Besides, if the CPU 110 needs to access other specific memory card 160, the SD host 142 firstly translates the access command into the SD format access command 172. Then, the SD host 142 transmits the SD format access command 172 to the bridge 144. The bridge 144 translates the SD format access command 172 into other specific memory card format access command 173. Furthermore, based on the other specific memory card format access command 173, the other specific memory card 160 compatible with the other specific memory card connection interface 145 performs data access.

If the northbridge/southbridge chipset 120 needs to store data into the other specific memory card 160, the route of sending the data and the related format conversions are the same as the access command to access the other specific memory card 160. If the CPU 110 needs to read data from the other specific memory card 160, the bridge 144 translates data read from the other specific memory card 160 into an SD format. Then, the SD host 142 translates the SD format data into a high-speed bus format data and transmits the high-speed bus format data to the northbridge/southbridge chipset 120 through the high-speed bus interface 141. The specifications of the other specific memory card 160 could include, for example, an MMC, an SM card, an MS, a CF card, or an xD-picture card. Because the specifications of the other specific memory card 160 are not compatible with the SD, access data from/to the other specific memory card 160 must utilize the bridge 144 corresponding to the other specific memory card format. The bridge 144 translates the SD format command 172 transmitted from the SD host 142 into the corresponding other specific memory card format command 173. Then, the other specific memory card 160 can be accessed through the other specific memory card connection interface 145.

Compared with the prior art, the card reader controlling apparatus based on SD protocol according to the present invention is capable of translating a high-speed bus format access command into an SD format access command, and thereby access the SD card 150 or the SDIO device 151. Therefore, by-passing or eliminating format conversions through other peripheral bus interfaces (such as a USB interface) will shorten transmission time of commands and data, and diminish computation complexity of a card reader. Therefore, the whole host system performance is promoted. In another aspect, when a user intends to access data from/to the other specific memory card, the card reader controlling apparatus of the present invention can utilize the other specific bridge to translate an SD format command into other specific memory card format command for supporting various types of memory card formats.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A card reader controlling apparatus based on SD (Secure Digital) protocol, comprising:
a high-speed bus interface transmitting either a high-speed bus format command or a high-speed bus format data;
at least one SD host translating the high-speed bus format command or data into an SD format command or an SD format data, or translating an SD format data received by the SD host into a high-speed bus format data for transmitting to the high-speed bus interface;
at least one SD card connection interface access data from a corresponding SD card based on the SD format command transmitted from the SD host, and transmitting the SD format data between the SD host and the SD card connection interface;
at least one bridge translating the SD format command or the SD format data transmitted by the SD host into other specific memory card format command or other specific memory card format data, or translating the other specific memory card format data into the SD format data for transmitting to the at least one SD host; and
at least one other specific memory card connecting interface storing the other specific memory card format data in a corresponding other specific memory card based on the other specific memory card format command transmitted from the bridge, or retrieving the SD format data from the corresponding other specific memory card to the SD bridge.

2. The card reader controlling apparatus according to the claim 1, further comprising at least one Secure Digital input/output (SDIO) connection interface receiving the SD format command transmitted from the SD host for access data from or to an input/output device compatible with the SDIO connection interface, and transmitting the SD format data between the SDIO connection interface and the SD host.

3. The card reader controlling apparatus according to the claim 1, wherein the other specific memory card format is a Multimedia Card (MMC) format.

4. The card reader controlling apparatus according to the claim 1, wherein the other specific memory card format is a Smart Media (SM) format.

5. The card reader controlling apparatus according to claim 1, wherein the other specific memory card format is a Memory Stick (MS) format.

6. The card reader controlling apparatus according to the claim 1, wherein the other specific memory card format is a Compact Flash (CF) format.

7. The card reader controlling apparatus according to the claim 1, wherein the other specific memory card is an xD-picture (xD) card format.

8. The card reader controlling apparatus according to the claim 1, wherein the high-speed bus interface is a Peripheral Component Interconnect Express (PCI-E) bus interface or a Peripheral Component Interconnect (PCI) bus interface.
